(19) United States
(12) Patent Application Publication
(10) Pub. No.: US 2024/0212968 A1
(43) Pub. Date: Jun. 27, 2024

(54) LENS FOR A CHARGED PARTICLE BEAM APPARATUS, CHARGED PARTICLE BEAM APPARATUS, AND METHOD OF FOCUSING A CHARGED PARTICLE BEAM

(71) Applicant: ICT Integrated Circuit Testing Gesellschaft für Halbleiterprüftechnik mbH, Heimstetten (DE)

(72) Inventors: Benjamin Cook, München (DE); Pieter Kruit, Delft (NL)

(73) Assignee: ICT Integrated Circuit Testing Gesellschaft für Halbleiterprüftechnik mbH, Heimstetten (DE)

(21) Appl. No.: 18/088,222

(22) Filed: Dec. 23, 2022

(51) Int. Cl. H01J 37/145; H01J 37/141

(52) U.S. Cl. CPC H01J 37/145; H01J 37/1413; H01J 37/28; H01J 2237/141

(57) ABSTRACT

A lens for a charged particle beam apparatus, the lens having lens components, is described. The lens includes a first magnetic lens having an upper pole piece and a middle pole piece; a second magnetic lens having the middle pole piece and a lower pole piece; a first coil arranged in the first magnetic lens and to provide a first magnetic field between the upper pole piece and the middle pole piece; a second coil arranged in the second magnetic lens and to provide a second magnetic field between the middle pole piece and the lower pole piece; and an electrostatic lens having an upper electrode and a lower electrode, wherein at least one of a first inner diameter defined by the upper pole piece and a second inner diameter defined by the middle pole piece is larger than a third inner diameter of the lower pole piece.

### TECHNICAL FIELD

Embodiments described herein relate to a lens for a charged particle beam in a charged particle beam system, for example in an electron microscope, particularly in a scanning electron microscope (SEM). Further, embodiments of the present disclosure relate to an objective lens and a method of focusing a charged particle beam on a sample. Embodiments further relate to a method with switching focusing operational modes.

Specifically, embodiments relate to a lens for a charged particle beam apparatus having lens components, a charged particle beam apparatus, and a method of focusing a charged particle beam with a lens having lens components on a sample.

### BACKGROUND

Modern semiconductor technology has created a high demand for structuring and probing samples in the nanometer or even in the sub-nanometer scale. Micrometer and nanometer-scale process control, inspection or structuring, is often done with charged particle beams, e.g. electron beams, which are generated, shaped, deflected and focused in charged particle beam systems, such as electron microscopes or electron beam pattern generators. For inspection purposes, charged particle beams offer a superior spatial resolution compared to, e.g., photon beams.

Apparatuses using charged particle beams, such as scanning electron microscopes (SEM), have many functions in a plurality of industrial fields, including, but not limited to, inspection of electronic circuits, exposure systems for lithography, detecting systems, defect inspection tools, and testing systems for integrated circuits. In such particle beam systems, fine beam probes with a high current density can be used. For instance, in the case of an SEM, the primary electron beam generates signal particles like secondary electrons (SE) and/or backscattered electrons (BSE) that can be used to image and/or inspect a sample.

Reliably inspecting and/or imaging samples with a charged particle beam system at a good resolution is, however, challenging. Further, particularly in the semiconductor industry, throughput, for example, for image generation is beneficially high. Low energy particle beams are beneficial for in-line inspection and/or imaging. In other operational modes, a high energy charged particle beam may be advantageous. The throughput influencing factors like the size of the field of view and the collection efficiency of signal particles, and factors like the resolution and the beam energy on a sample, for example, a wafer, may contradict each other for beneficial design of electro-optical components.

In light of the above, providing an improved lens for a charged particle beam apparatus, an improved charged particle beam apparatus, and an improved method of focusing a charged particle beam are beneficial.

### SUMMARY

In light of the above, a lens for a charged particle beam apparatus, a charged particle beam apparatus, and a method of focusing the charged particle beam are provided according to the independent claims.

According to an embodiment, a lens for a charged particle beam apparatus, the lens having lens components, is provided. The lens includes a first magnetic lens having an upper pole piece and a middle pole piece: a second magnetic lens having the middle pole piece and a lower pole piece: a first coil arranged in the first magnetic lens and to provide a first magnetic field between the upper pole piece and the middle pole piece: a second coil arranged in the second magnetic lens and to provide a second magnetic field between the middle pole piece and the lower pole piece: and an electrostatic lens having an upper electrode and a lower electrode, wherein at least one of a first inner diameter defined by the upper pole piece and a second inner diameter defined by the middle pole piece is larger than a third inner diameter of the lower pole piece.

According to an embodiment, a charged particle beam apparatus is provided. The charged particle beam apparatus includes a stage configured to support a sample, a charged particle beam source adapted to generate a charged particle beam: a lens according to any one of the embodiments described herein, and a detector configured to detect signal particles generated upon impingement of the charged particle beam on the sample.

According to an embodiment, a method of focusing a charged particle beam on a sample is provided. The lens has lens components. The method includes providing a first current to a first magnetic lens: providing a second current to a second magnetic lens, wherein the first magnetic lens and the second magnet lens have one common pole piece: and providing a voltage to a lower electrode of an electrostatic lens to decelerate the charged particle beam, particularly wherein the lower electrode is a portion of a lower pole piece of the lens.

Further advantages, features, aspects and details that can be combined with embodiments described herein are evident from the dependent claims, the description and the drawings.

### BRIEF DESCRIPTION OF THE DRAWINGS

So that the manner in which the above recited features of the present disclosure can be understood in detail, a more particular description, briefly summarized above, may be had by reference to embodiments. The accompanying drawings relate to one or more embodiments and are described in the following.

FIG. 1 shows a schematic view of a charged particle system according to embodiments described herein.

FIG. 2 shows a schematic view of a lens according to embodiments described herein.

FIG. 3 shows a flow chart illustrating a method of correcting, i.e. reducing, aberration of a charged particle beam in a charged particle beam system according to embodiments described herein.

### DETAILED DESCRIPTION

Reference will now be made in detail to the various embodiments, one or more examples of which are illustrated in the figures. Within the following description of the drawings, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Embodiments of the present disclosure provide a double magnetic lens, and particularly a double magnetic lens allowing for different operation modes. An anisotropic coma and other anisotropic aberrations can be reduced. Better resolution can be achieved. Further, additionally or alternatively, good resolution can be provided for various landing energies. The double magnetic lens includes three pole pieces, wherein the middle pole piece is shared by an upper magnetic lens and a lower magnetic lens, for example, to save space.

According to an embodiment, a lens for a charged particle beam apparatus, the lens having lens components, is provided. The lens includes a first magnetic lens having an upper pole piece and a middle pole piece and a second magnetic lens having the middle pole piece and a lower pole piece. A first coil is arranged in the first magnetic lens and to provide a first magnetic field between the upper pole piece and the middle pole piece. A second coil is arranged in the second magnetic lens and to provide a second magnetic field between the middle pole piece and the lower pole piece. The lens includes an electrostatic lens having an upper electrode and a lower electrode, wherein at least one of a first inner diameter defined by the upper pole piece and a second inner diameter defined by the middle pole piece is larger than a third inner diameter of the lower pole piece.

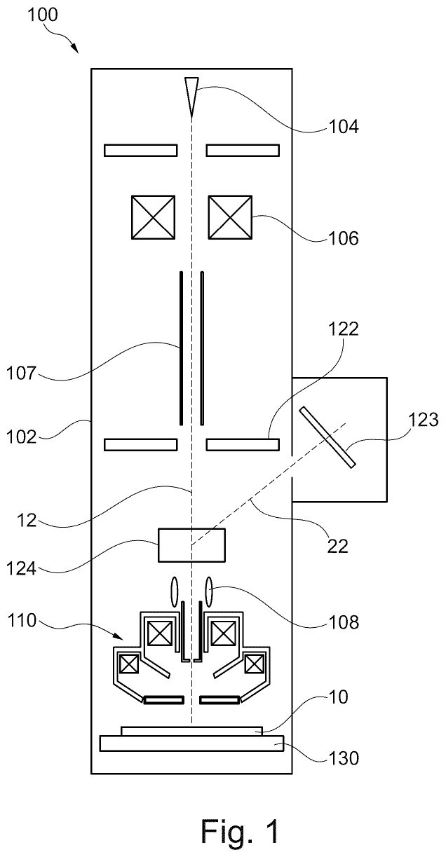

FIG. 1 is a schematic view of a charged particle beam apparatus 100 for inspecting and/or imaging a sample 10 or portions of a sample according to embodiments described herein. The charged particle beam apparatus 100 includes a column 102. The column 102 can provide a vacuum enclosure such that the charged particle beam travels under vacuum. The charged particle beam apparatus 100 includes a charged particle beam source 104. A charged particle beam source can be configured to emit a charged particle beam. The charged particle beam may be an electron beam. The charged particle beam may propagate along an optical axis 12. The charged particle beam apparatus 100 further includes a sample stage 130. A lens 110, such as an objective lens, focuses the charged particle beam, i.e., a primary charged particle beam, on the sample 10. The sample can be placed on the sample stage 130. The focusing lens may be an objective lens. The lens 110 can be a lens according to any of the embodiments described herein.

A condenser lens 106 or a condenser lens system may be arranged downstream of the charged particle beam source 104. The condenser lens system can collimate the charged particle beam propagating toward the lens 110. Further, an electrode or tube 107 configured to accelerate the beam can be provided. The electrode or tube can be provided on a high potential. The high potential can, for example, be a high positive potential relative to the charged particle beam source to accelerate an electron beam.

The electrode or tube 107 may provide an acceleration section for accelerating the electron beam, e.g., to an electron energy of 5 keV or more. The electrons may be first accelerated by an extractor electrode that is set on a positive potential relative to an emission tip of the charged particle beam source 104. The electrode or tube may provide for further beam acceleration. In some embodiments, the charged particles, for example, electrons, are accelerated to an electron energy of 10 keV or more, 30 keV or more, or even 50 keV or more. A high electron energy within the column can reduce negative effects of electron-electron interactions. A high beam energy within the charged particle beam apparatus can improve an imaging resolution.

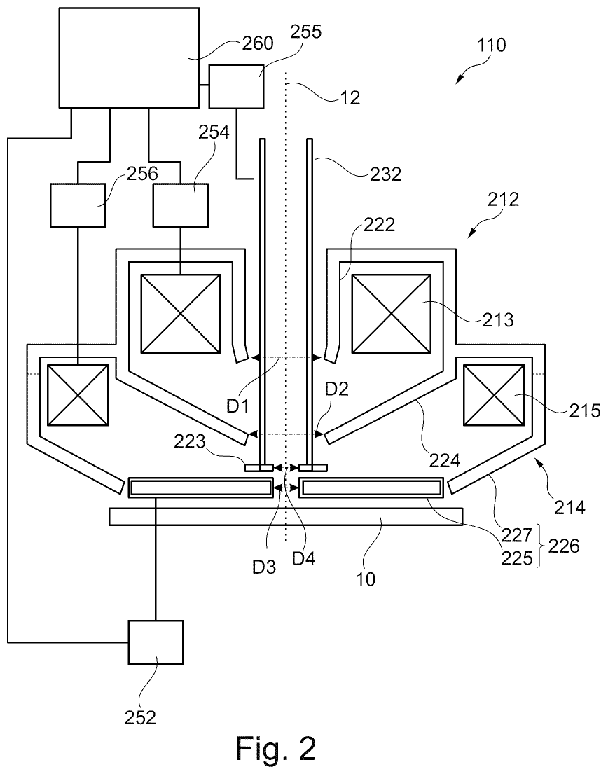

The charged particle beam apparatus 100 further includes one or more charged particle detectors, particularly one or more electron detectors. A charged particle detector, such as on-axis detector 122 and/or off-axis detector 123, can detect signal particles emitted from the sample 10. The signal electrons are emitted from the sample upon impingement of the primary charged particle beam on the sample. The one or more charged particle detectors can detect signal electrons, for example, secondary electrons and/or backscattered electrons. As exemplarily shown in FIG. 2, a charged particle detector being an in-lens detector may additionally or alternatively be provided.

According to some embodiments, which can be combined with other embodiments described herein, a beam separation unit 124 can be provided. Particularly for a charged particle beam apparatus including an off-axis detector, the signal charged particle beam 22 can be separated from the primary charged particle beam traveling along the optical axis 12.

The beam separation unit 124 can include a magnetic deflector, wherein the beam deflection of the signal charged particle beam 22 results from the signal charged particle beam traveling in the opposite direction as compared to the primary charged particle beam.

An image generation unit (not shown) may be provided. The image generation unit can be configured to generate one or more images of the sample 10. The image generation unit can generate the one or more images based on the signal received from the one or more charged particle detectors. The image generation unit can forward the one or more images of the sample to a processing unit (not shown).

The sample stage 130 may be a movable stage. In particular, the sample stage 130 may be movable in the Z-direction, i.e., in the direction of the optical axis 12, such that the distance between the focusing lens 110 and the sample stage 130 can be adjusted. By moving the sample stage 130 in the Z-direction, the sample 10 can be moved to different “working distances”. Further, the sample stage 108 may also be movable in a plane perpendicular to the optical axis 12 (also referred to herein as the X-Y-plane). By moving the sample stage 130 in the X-Y-plane, a specified surface region of the sample 10 can be moved into an area, e.g. a field of view (FOV), below the focusing lens 110, such that the specified surface region can be imaged by focusing the charged particle beam on the surface region of the sample.

The beam-optical components of the charged particle beam apparatus 100 can be placed in a vacuum chamber of the column 102 that can be evacuated. A vacuum can be beneficial for propagation of the charged particle beam, for example, along the optical axis 12 from the charged particle beam source 104 toward the sample stage 130. The charged particle beam may hit the sample under a sub-atmospheric pressure, e.g. a pressure below 10-3 mbar or a pressure below 10-5 mbar.

For example, the charged particle beam apparatus 100 may be an electron microscope, particularly a scanning electron microscope. According to some embodiments, which can be combined with other embodiments described herein, a scan deflector 108 may be provided for scanning the charged particle beam, particularly over a surface of the sample along a predetermined scanning pattern, for example, in the X-direction and/or in the Y-direction.

One or more surface regions of the sample 10 can be inspected and/or imaged with the charged particle beam apparatus 100. The term “sample” as used herein may also be referred to as the “specimen” and may relate to a substrate, for example, with one or more layers or features formed thereon, a semiconductor wafer, a glass substrate, a flexible substrate, such as a web substrate, or another sample that is to be inspected. The sample can be inspected for one or more of (1) imaging a surface of the sample, (2) measuring dimensions of one or more features of the sample, e.g. in a lateral direction, i.e. in the X-Y-plane, (3) conducting critical dimension measurements and/or metrology, (4) detecting defects, and/or (5) investigating the quality of the sample. According to some embodiments, which can be combined with other embodiments described herein, the flexibility of landing energies may beneficially be utilized for EBI (electron beam inspection) systems, which may have higher beam landing energies.

According to an embodiment, a charged particle beam apparatus is provided. The charged particle beam apparatus can, for example, be a charged particle beam scanning microscope. The charged particle beam apparatus includes a stage configured to support a sample: a charged particle beam source adapted to generate a charged particle beam: a lens according to any of the embodiments described herein: and a detector configured to detect signal particles generated upon impingement of the charged particle beam on the sample.

FIG. 2 illustrates a lens 110 to describe various embodiments of the present disclosure. The lens 110 can be an objective lens and, particularly, a double magnetic lens. The lens 110 includes a first magnetic lens 212 and a second magnetic lens 214. The first magnetic lens 212 can be an upper magnetic lens. The first magnetic lens includes a coil, for example, a first coil 213. The second magnetic lens 214 can be a lower magnetic lens. The second magnetic lens includes a coil, for example, a second coil 215.

The first magnetic lens 212 includes an upper pole piece 222 and the middle pole piece 224. The second magnetic lens 214 includes the middle pole piece 224 and a lower pole piece 226. The middle pole piece is shared by the first magnetic lens, i.e. the upper magnetic lens, and the second magnetic lens, i.e. the lower magnetic lens. Accordingly, space-saving can be provided for the lens 110 and the magnetic field of the first magnetic lens and the second magnetic lens can be closer to each other. The first coil 213 is configured and/or arranged to provide a first magnetic field between the upper pole piece and the middle pole piece. The second coil 215 is configured and/or arranged to provide a second magnetic field between the middle pole piece and the lower pole piece.

The lens according to embodiments of the present disclosure includes lens components. The lens components include the first magnetic lens and the second magnetic lens. The lens components further include an electrostatic lens. The electrostatic lens includes an upper electrode 232 and a lower electrode. The lower electrode can be provided by a portion of the lower pole piece 226. Further space-saving can be provided. According to embodiments of the present disclosure, the lower pole piece 226 includes a first portion 227 and a second portion 225. The first portion and the second portion are spaced apart from each other. According to some embodiments, which can be combined with other embodiments described herein, a gap can be provided between the first portion 227 of the lower pole piece 226 and the second portion 225 of the lower pole piece 226. The gap allows for applying a voltage to the second portion of the lower pole piece3, i.e. the lower electrode of the electrostatic lens component. The lens further allows to have a magnetic flux provided from the first portion of the lower pole piece to the second portion of the lower pole piece. Electrostatic excitation of the electrostatic lens and magnetic excitation of the second magnetic lens 214 can be separated. According to some embodiments, the lower pole piece has a first portion and a second portion spaced apart from the first portion, wherein the second portion of the lower pole piece can be provided as the lower electrode. As shown in FIG. 2, the gap can be provided at a bottom of the lower pole piece. As indicated by the dashed line in FIG. 2, the gap may also be provided further up in the lower pole piece.

The second portion 225 of the lower pole piece can be connected to a power supply, i.e. a voltage supply 252. The upper electrode 232 of electrostatic lens can be connected to a voltage supply 255. An electrostatic field between the upper electrode 232 and the lower electrode, e.g. the second portion 225 of the lower pole piece 226, can be generated. Alternatively, one power supply can be connected to the lower electrode and the upper electrode of the electrostatic lens. The electrostatic field can, in some operational modes, provide a retarding field for the primary charged particle beam and an accelerating field for the signal charged particle beam

As shown in FIG. 2, the lens 110 may further include a first power supply 254. The first power supply 254 is connected to the first coil 213 and may provide a first current to the first coil for excitation of the first magnetic lens 212. The lens 110 may further include the second power supply 256. The second power supply 256 is connected to the second coil 215 and may provide a first current to the first coil for excitation of the second magnetic lens 214. The voltage supply 252, the first power supply 254 and the second power supply 256 can be connected to a controller 260. The controller controls the currents and voltages for operation of the lens 110 and allows for various modes of operation, particularly switching between operation modes of the lens 110.

According to an embodiment, a lens for a charged particle beam apparatus, particularly an objective lens is provided. The lens includes lens components. The lens components include a first magnetic lens having an upper pole piece and a middle pole piece: a second magnetic lens having the middle pole piece and a lower pole piece, the lower pole piece having a first portion and a second portion spaced apart from the first portion: a first coil arranged in the first magnetic lens and to provide a first magnetic field between the upper pole piece and the middle pole piece: a second coil arranged in the second magnetic lens and to provide a second magnetic field between the middle pole piece and the lower pole piece: and an electrostatic lens having an upper electrode and the second portion of the lower pole piece as a lower electrode.

According to some embodiments, which can be combined with other embodiments described herein, the lens further includes a first power supply connected to the first coil and configured to provide a first current to the first coil, and a second power supply connected to the second coil configured to provide a second current to the second coil, the second current being independent from the first current. According to some embodiments, which can be combined with other embodiments described herein, a voltage supply connected to the lower electrode of the electrostatic lens can be configured to provide a retarding field within the electrostatic lens.

The controller 260 controls the operation of the lens 110. The lower pole piece of the second magnetic lens forms together with the upper electrode 232 and electrostatic lens. A voltage can be provided between the upper electrode 232 and the lower electrode of the electrostatic lens. Particularly, the voltage on the lower electrode, i.e. the second portion 225 of lower pole piece, may be utilized to control the electrostatic field on the sample, e.g. a wafer. For example, acceleration of the signal electrodes from the sample can be controlled.

The first magnetic lens, the second magnetic lens, and the electrostatic lens are used to focus the charged particle beam on the sample. Particularly, the first current in the first coil 213 and the second current in the second coil 215 can be utilized for different modes of operation. Different lens properties can be provided.

In one operational mode, anisotropic coma or anisotropic aberrations, for example, anisotropic dispersion, can be corrected, i.e. reduced. According to some embodiments, which can be combined with other embodiments described herein, anisotropic coma or other anisotropic aberrations can be reduced to zero. The performance of the lens and/or the charged particle beam apparatus can be improved, particularly for beams travelling off-axis, i.e. distant from the optical axis 12, e.g. for scanning of the beam and/or for increasing the field of view. For example, the first current in the first coil can be provided by the formula (1) I₁=−k I₂, wherein I₂ is the second current in the second coil and k is a positive constant. Accordingly, in a first operational mode, the first current generates a first magnetic field springs with an opposite sign than a second magnetic field strength generated by the second current. Formula (1) applies if the winding direction of the first coil 213 has the same winding direction as the second coil 215. If the binding directions of the first coil and the second coil would be different, formula (2) I₁=k I₂, wherein I₂ is the second current in the second coil and k is a positive constant can apply to provide for the opposite magnetic field strengths. The opposite magnetic field strengths allow to correct, i.e. to reduce, anisotropic coma or other anisotropic aberrations, e.g. anisotropic dispersion.

According to some embodiments, which can be combined with other embodiments described herein, a pre-deflection, i.e. pre-lens deflection, and a post-deflection, i.e. a post-lens deflection may be provided by respective deflectors. The post-lens deflection may also be an in-lens deflection. The combination of pre-deflection and post-deflection allows adjustment of the beam path of the primary charged particle beam through the lens in order to further correct, i.e. reduce, the anisotropic coma and other anisotropic aberrations. For example, the primary charged particle beam can be guided through a coma-free point of the lens, particularly wherein the beam path can be adjusted for different operational modes.

In a further operational mode, the first current can be zero and the second current can be non-zero. Accordingly, the distance of the magnetic lens from the sample is reduced. Aberrations can be reduced and a high resolution can be provided. Yet, the magnetic field of the second magnetic lens 214 may immerse with the sample. Operating the lens 110 as an immersion lens, wherein the magnetic field may immerse with the sample may be advantageous or disadvantageous for different applications and/or a reduced field strength of the magnetic lens, may limit the landing energies.

Accordingly, in a yet further mode of operation, the second current can be zero and the first current can be non-zero. The magnetic field on the sample is low, i.e. immersion of the magnetic field with the sample can be reduced or avoided. In the yet further mode of operation, aberrations may be larger but there are less restrictions on the landing energy.

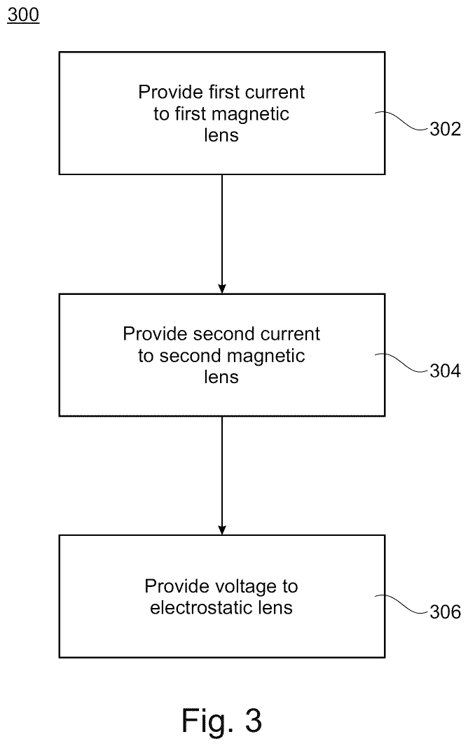

FIG. 3 shows a flow chart illustrating a method 300 focusing a charged particle beam with a lens having lens components on a sample. The first current can be provided to a first magnetic lens as shown by operation 302. Particularly, the first current can be provided to a first coil 213 of the first magnetic lens. The first magnetic lens can be an upper magnetic lens having a common pole piece with the second magnetic lens being a lower magnetic lens. According to operation 304, a second current is provided to the second magnetic lens 214, particularly to a second coil 215 of the second magnetic lens. Further, a voltage is provided to an electrostatic lens (see operation 306). For example, a voltage can be provided to a lower electrode of the electrostatic lens to decelerate the charged particle beam. According to embodiments of the present disclosure, the lower electrode is a portion of the lower pole piece of the lens 110.

According to an embodiment, a method of focusing a charged particle beam with a lens having lens components on a sample is provided. The method includes providing a first current to a first magnetic lens: providing a second current to a second magnetic lens, wherein the first magnetic lens and the second magnet lens have one common pole piece: and providing a voltage to a lower electrode of an electrostatic lens to decelerate the charged particle beam, wherein the lower electrode is a portion of a lower pole piece of the lens.

A controller 260 can be used to switch between different modes of operation. Particularly, the first current in the first coil and the second current in the second coil can be adjusted to switch between at least a first operational mode and the second operational mode. According to some embodiments, which can be combined with other embodiments described herein, the voltage of the lower electrode of the electrostatic lens can be adjusted to further generate operational modes by marrying the landing energy of the primary charged particle beam on the sample 10.

As described above, embodiments of the present disclosure can allow for adjusting at least one of the first current and the second current to switch between at least a first operational mode and a second operational mode. According to the first operational mode, the first current, particularly the first current in a first or upper magnetic lens, generates a first magnetic field strength with an opposite sign than a second magnetic field strength generated by the second current, particularly the second current in a second or lower magnetic lens. According to some embodiments, which can be combined with other embodiments described herein, at least one of the first current and the second current can be zero in a second operational mode. Further, in the third operational mode, the other one of the first current and the second current can be zero.

According to yet further embodiments, which can be combined with other embodiments described herein, operational modes may also be generated by having a non-zero first current and a non-zero second current, wherein at least one of the first current and the second current can be increased or reduced to increase or reduce the respective excitation of the first magnetic lens or the second magnetic lens. According to some embodiments, which can be combined with other embodiments described herein, switching between operational modes may vary the amount of immersion of the magnetic field on the sample. Further, anispotropic coma can be corrected, i.e. reduced. For example, anisotropic coma can be reduced to zero. Additionally or alternatively, aberrations other than anisotropic coma and effects on the charged particle beam landing energies can be controlled by varying one or more of the first current, a second current, and the voltage applied to the lower electrode of the electrostatic lens.

The operational modes allow to provide a double magnetic lens with zero anisotropic coma. Accordingly, the field of view can be increased which may, in turn, reduce the stage movement. The reduced movement of the sample stage 130 can increase the throughput of the charged particle beam apparatus 100. According to yet further embodiments, which can be combined with other embodiments described herein, the reduced or zero anisotropic coma may result in increased tilt angles. Accordingly, 3D imaging can be provided. This may be useful for applications such as imaging a gate “all around”, i.e. from different sides of the gate, for example, three, four or more sides of a gate on a wafer. According to some embodiments, which can be combined with other embodiments described herein, a lens of a method of focusing the charged particle beam can be aligned according to any of the embodiments described herein.

According to some embodiments, which can be combined with other embodiments described herein, tilt angles of up to 45° can be provided at a resolution of 10 nm or below. According to yet further applications, critical dimensioning measurements can be provided and/or improved on large FOV applications, such as imaging of “word line pads”.

Reverting to FIG. 2, the lens 110 provides the electrostatic lens being part of the one or more magnetic lenses, and particularly the lower magnetic lens. The number of components of the lens can be reduced as compared to a lens assembly, in which two magnetic lenses are provided individually and in addition to an electrostatic lens.

Accordingly, the available space is increased. Higher collection efficiency of signal particles or detection efficiency of signal particles can be provided.

FIG. 2 illustrates various diameters within the lens 110. A diameter of a component of the lens can be defined as the diameter of a cylinder with the maximum radius that can be provided within the respective portion of the lens. As shown in FIG. 2, a first inner diameter D1 can be provided by the upper pole piece 222, i.e. the upper pole piece of the first magnetic lens 212. Further, a second inner diameter D2 can be provided by the middle pole piece 224, i.e. the lower pole piece of the first magnetic lens and the upper pole piece of the second magnetic lens. A third inner diameter D3 can be provided by the second portion of the lower pole piece 226. In other words, the third inner diameter D3 can be provided by the lower electrode of the electrostatic lens.

The lower electrode of the electrostatic lens is close to the sample 10 or the sample stage 130, respectively. Accordingly, the third diameter can be comparably small as being close to the position at which the signal electrons are accelerated away from the sample 10.

The first inner diameter and/or the second inner diameter can be larger than the third inner diameter. Accordingly, the detection efficiency of signal electrons can be increased. According to some embodiments, which can be combined other embodiments described herein, at least one of the first inner diameter and the second inner diameter, particularly the first diameter and the second diameter, can be at least 3 times larger than the third inner diameter. For example, at least one of the first inner diameter and the second inner diameter, particularly the first diameter and the second diameter can be at least 5 times larger than the third inner diameter, for example about 10 times larger. According to some embodiments, which can be combined with other embodiments described herein, the first inner diameter and the second inner diameter can be substantially the same, i.e. within a deviation of +−10%.

FIG. 2 shows an in-lens detector 223, which may be provided in addition (or alternatively) to the on-axis detector 122 and the off-axis detector 123 shown in FIG. 1. The upper electrode 232 of the electrostatic lens can have a fourth diameter D4. According to some embodiments, which can be combined with other embodiments described herein, the in-lens detector 223 can be coupled to or integrally formed with the upper electrode of the electrostatic lens.

The fourth diameter D4 can be smaller than the first diameter D1 and the second diameter D2. Accordingly, signal electrons can pass through the region of the first diameter D1 and the second diameter D2 and can be detected by one or more of the detectors of the charged particle beam apparatus, such as the in-lens detector. For detection with an on-axis detector 122 and/or off-axis detector as shown in FIG. 1, also the fourth diameter of the upper electrode may be comparably large.

According to an embodiment, a charged particle beam apparatus can be provided. The charged particle beam apparatus includes a stage configured to support a sample: a charged particle beam source adapted to generate a charged particle beam: a lens according to embodiments described herein, and a detector configured to detect signal particles generated upon impingement of the charged particle beam on the sample.

Various embodiments are described, some of which are provided in the following clauses. Clause 1. A lens for a charged particle beam apparatus, the lens having lens components including a first magnetic lens having an upper pole piece and a middle pole piece: a second magnetic lens having the middle pole piece and a lower pole piece: a first coil arranged in the first magnetic lens and to provide a first magnetic field between the upper pole piece and the middle pole piece: a second coil arranged in the second magnetic lens and to provide a second magnetic field between the middle pole piece and the lower pole piece: and an electrostatic lens having an upper electrode and a lower electrode, wherein at least one of a first inner diameter defined by the upper pole piece and a second inner diameter defined by the middle pole piece is larger than a third inner diameter of the lower pole piece.

Clause 2. The lens according to clause 1, wherein at least one of the first inner diameter and the second inner diameter is at least 3 times larger, particularly at least 5 times larger, than the third inner diameter.

Clause 3. The lens according to any of clauses 1 to 2, wherein the lower pole piece has a first portion and a second portion spaced apart from the first portion, and wherein the lower electrode of the electrostatic lens is provided by the second portion.

Clause 4. The lens according to any of clauses 1 to 3, further including a first power supply connected to the first coil and configured to provide a first current to the first coil: and a second power supply connected to the second coil configured to provide a second current to the second coil, the second current being independent from the first current.

Clause 5. The lens according to any of clauses 1 to 4, further including one or more voltage supplies connected to at least one of the upper electrode and the lower electrode of the electrostatic lens and configured to provide a retarding field for a primary charged particle beam between the upper electrode and the lower electrode of the electrostatic lens and an accelerating field for the signal charged particle beam.

Clause 6. The lens according to any of clauses 1 to 5, wherein a fourth inner diameter of the upper electrode is smaller than the first inner diameter.

Clause 7. A charged particle beam apparatus, including a stage configured to support a sample: a charged particle beam source adapted to generate a charged particle beam: a lens according to any one of clauses 1 to 6: and a detector configured to detect signal particles generated upon impingement of the charged particle beam on the sample.

Clause 8. The charged particle beam apparatus according to clause 7, wherein the stage is configured to support a sample at a position such that said lens is situated between the charged particle beam source and the sample.

Clause 9. A method of focusing a charged particle beam with a lens having lens components on a sample. The method includes providing a first current to a first magnetic lens: providing a second current to a second magnetic lens, wherein the first magnetic lens and the second magnet lens have one common pole piece: and providing a voltage to a lower electrode of an electrostatic lens to decelerate the charged particle beam, wherein the lower electrode is a portion of a lower pole piece of the lens.

Clause 10. The method of clause 9, further including adjusting at least one of the first current and the second current to switch between at least a first operational mode and a second operational mode.

Clause 11. The method of clause 10, wherein in the first operational mode the first current generates a first magnetic field strength with an opposite sign than a second magnetic field strength generated by the second current.

Clause 12. The method of any of clauses 10 to 11, wherein in the second operation mode, one of the first current and the second current is zero.

Clause 13. The method of clause 12, wherein in a third operational mode, the other one of the first current and the second current is zero.

Clause 14. The method of any of clauses 10 to 13, wherein switching between the first operational mode and the second operation mode varies an amount of immersion of a magnetic field on the sample.

Clause 15. The method of any of clauses 9 to 14, wherein the lens is a lens according to any of clauses 1 to 10.

Embodiments of the present disclosure allow to combine the benefits of a lens having large polepieces at a relatively large distance utilized for high beam energy and a lens having small diameter pole pieces at a shorter distance utilized for high resolution for a low energy beam and a declaration of the beam as close to the magnetic lens as possible.

While the foregoing is directed to embodiments, other and further embodiments may be devised without departing from the basic scope, and the scope thereof is determined by the claims that follow.

1. A lens for a charged particle beam apparatus, the lens having lens components comprising:
a first magnetic lens having an upper pole piece and a middle pole piece;
a second magnetic lens having the middle pole piece and a lower pole piece;
a first coil arranged in the first magnetic lens and to provide a first magnetic field between the upper pole piece and the middle pole piece;
a second coil arranged in the second magnetic lens and to provide a second magnetic field between the middle pole piece and the lower pole piece; and
an electrostatic lens having an upper electrode and a lower electrode,
wherein at least one of a first inner diameter defined by the upper pole piece and a second inner diameter defined by the middle pole piece is larger than a third inner diameter of the lower pole piece.

2. The lens according to claim 1, wherein at least one of the first inner diameter and the second inner diameter is at least 3 times larger, particularly at least 5 times larger, than the third inner diameter.

3. The lens according to claim 1, wherein the lower pole piece has a first portion and a second portion spaced apart from the first portion, and wherein the lower electrode of the electrostatic lens is provided by the second portion.

4. The lens according to claim 1, further comprising:
a first power supply connected to the first coil and configured to provide a first current to the first coil; and
a second power supply connected to the second coil configured to provide a second current to the second coil, the second current being independent from the first current.

5. The lens according to claim 1, further comprising:
one or more voltage supplies connected to at least one of the upper electrode and the lower electrode of the electrostatic lens and configured to provide a retarding field for a primary charged particle beam between the upper electrode and the lower electrode of the electrostatic lens and an accelerating field for the signal charged particle beam.

6. The lens according to claim 1, wherein a fourth inner diameter of the upper electrode is smaller than the first inner diameter.

7. A charged particle beam apparatus, comprising:
a stage configured to support a sample;
a charged particle beam source adapted to generate a charged particle beam;
a lens according to claim 1;
and a detector configured to detect signal particles generated upon impingement of the charged particle beam on the sample.

8. The charged particle beam apparatus according to claim 7, wherein the stage is configured to support a sample at a position such that said lens is situated between the charged particle beam source and the sample.

9. A method of focusing a charged particle beam with a lens having lens components on a sample, comprising:
providing a first current to a first magnetic lens;
providing a second current to a second magnetic lens, wherein the first magnetic lens and the second magnet lens have one common pole piece; and
providing a voltage to a lower electrode of an electrostatic lens to decelerate the charged particle beam, wherein the lower electrode is a portion of a lower pole piece of the lens.

10. The method of claim 9, further comprising:
adjusting at least one of the first current and the second current to switch between at least a first operational mode and a second operational mode.

11. The method of claim 10, wherein in the first operational mode the first current generates a first magnetic field strength with an opposite sign than a second magnetic field strength generated by the second current.

12. The method of claim 10, wherein in the second operation mode, one of the first current and the second current is zero.

13. The method of claim 12, wherein in a third operational mode, the other one of the first current and the second current is zero.

14. The method of claim 10, wherein switching between the first operational mode and the second operation mode varies an amount of immersion of a magnetic field on the sample.

15. A method of focusing a charged particle beam on a sample, the charged particle beam focused with a lens having lens components comprising:
a first magnetic lens having an upper pole piece and a middle pole piece;
a second magnetic lens having the middle pole piece and a lower pole piece;
a first coil arranged in the first magnetic lens and to provide a first magnetic field between the upper pole piece and the middle pole piece;
a second coil arranged in the second magnetic lens and to provide a second magnetic field between the middle pole piece and the lower pole piece; and
an electrostatic lens having an upper electrode and a lower electrode, wherein at least one of a first inner diameter defined by the upper pole piece and a second inner diameter defined by the middle pole piece is larger than a third inner diameter of the lower pole piece;
wherein the method comprising:
providing a first current to the first magnetic lens;
providing a second current to the second magnetic lens; and
providing a voltage to the lower electrode of the electrostatic lens to decelerate the charged particle beam, wherein the lower electrode is a portion of the lower pole piece of the lens.
